(19) United States
(12) Patent Application Publication
(10) Pub. No.: US 2018/0299779 A1
(43) Pub. Date: Oct. 18, 2018

(54) METHOD FOR MAKING A LITHOGRAPHIC PRINTING PLATE

(71) Applicant: PhotoCentric Limited, Peterborough (GB)

(72) Inventor: Paul Holt, Peterborough (GB)

(21) Appl. No.: 15/766,993

(22) PCT Filed: Nov. 4, 2016
(86) PCT No.: PCT/GB2016/053434

§ 371 Date: Apr. 9, 2018

(30) Foreign Application Priority Data
Nov. 6, 2015 (GB) 1519648.8

(51) Int. Cl. G03F 7/20; G03F 7/029; G03F 7/032; G03F 7/033; B41C 1/10

(52) U.S. Cl. CPC G03F 7/2057; G03F 7/029; B41C 2201/10; G03F 7/033; B41C 1/1041; G03F 7/0325

(57) ABSTRACT

This application relates to lithographic printing plates, methods of making said plates, and precursor plates for use in said methods.

### FIELD OF THE INVENTION

This invention describes an innovative method for making a lithographic printing plate by direct exposure to an image formed by a daylight emitting display screen.

### BACKGROUND OF THE INVENTION

Lithography is widely used for the microfabrication of for example, lithographic printing plates, printed boards, color filters, large scale integrated circuits (LSI), thin film transistors (TFT), liquid crystal displays (LCD), plasma display panels (PDP) and semiconductor packagings (TAB), wherein an image forming material with a layer of a photosensitive composition formed on its surface is image-wise exposed through a mask.

Lithographic printing is based upon the immiscibility of oil and water. A printing plate has an image area and a non-image area formed of materials such that the oily material or ink is preferentially retained by the image area and the aqueous solution is preferentially retained by the non-image area. When a suitably prepared surface is wetted out with water and an ink is then applied, the background or non-image area retains the water and repels the ink while the image area attracts the ink and repels the water. The ink that is present on the image area is then transferred to the surface of the material to be printed by pressure. Commonly the ink is transferred to an intermediate surface or printing blanket first, which in turn is transferred to the surface of the material upon which the image is to be reproduced.

There are two possible ways of using radiation-sensitive compositions for the preparation of printing plates, negative and positive working. In negative working printing plates the exposed regions are hardened with radiation and the unexposed regions are washed off during development. In positive working printing plates, the exposed regions are dissolved in a developer and the unexposed regions become an image.

Negative-working lithographic printing plates are prepared from negative-working radiation-sensitive compositions that are formed from polymers which polymerise when exposed to radiation, typically UV light. Upon image-wise exposure of the light-sensitive layer the exposed image areas become water insoluble while the unexposed areas remain water soluble. Typically the plate will include an interlayer to control the bonding of the radiation-sensitive layer to the substrate. The plate is developed with water to remove the photosensitive resin in the unexposed areas.

Commercially available photosensitive based printing plates most commonly use an anodized and roughened aluminium sheet as a support, or lithographic precursor plate. Lithographic printing plates of this type provide high resilience and excellent print resolution.

Negative-working lithographic printing plates have a radiation-sensitive composition which includes a photo-crosslinkable polymer, examples of this are described in U.S. Pat. No. 3,622,320 to Shimizu et al, U.S. Pat. No. 3,702,765 to Laakso and U.S. Pat. No. 3,929,489 to Arcasi, herein incorporated by reference in their entirety.

The photo-crosslinkable polymer is formed on a support layer and is covered with a protective layer. The photosensitive layer will typically contain an ethylenic monomer containing an unsaturated double bond, a sensitizing pigment and a radical generator. It may also contain colouring agents, plasticizers, and thermal polymerization inhibitors.

These compositions may have sensitivity to 480 nm wavelength light when exposed to a xenon lamp, or be responsive to radiation energies required for image formation at 488 nm using an argon ion laser or a composition responsive to light of 442 nm in the case of using a helium-cadmium laser.

Recent developments have led to lithographic printing plates that can be developed in the near UV and visible spectral ranges by lasers emitting around 420 nm. These require considerably lower energy usage than higher wavelength lasers. These near visible or blue light lasers are also considerably lower in cost than their higher wavelength alternatives, so the capital equipment can be provided at lower prices. They also provide the potential for shorter exposure times and therefore faster processing.

For these reasons efforts have been made to increase the sensitivity of near UV region photosensitive compositions in recent years. Near UV laser light, or blue light laser radiation, has a wavelength of between 360 nm and 480 nm with a peak of between 430 nm and 460 nm.

US 20050053862 to Kondo et al, herein incorporated in its entirety, discloses photopolymerisable compositions containing titanocene comprising a triazine compound to enhance the reactivity in the daylight region.

CN 1,591,186, herein incorporated in its entirety, also discloses photopolymerisable compositions containing titanocene comprising a triazine compound to enhance the reactivity and plate resistance.

Although the use of titanocene greatly increases the sensitivity of the reaction to blue light, the resolution of the printing plate is often compromised by the reflected high intensity laser light being scattered after striking highly reflective substrates such as the metal base. The resultant resolution can be greatly reduced by this reflected or scattered light, since light penetrates into the geometrical shadow regions and then effects crosslinking of the radiation-sensitive polymers.

U.S. Pat. No. 5,011,755 to Rohde et al, herein incorporated in its entirety, discloses the addition of 3-ketocoumarins to titanocene compounds in relatively low concentrations to absorb this excess reflected light while still attempting to retain high photosensitivity in the system.

U.S. Pat. No. 5,811,218 to Kaji et al, herein incorporated in its entirety, similarly discloses photopolymerisable compositions used to make letterpresses, relief images and photoresists with improved photosensitive properties within the visible region comprising a titanocene compound and a coumarin and/or an azabenzalcyclohexanone compound as stabilisers/sensitisers.

JP 3,187,569, herein incorporated in its entirety, discloses a photosensitive composition containing a titanocene compound, an acridine compound, and a triazine compound.

JP 6-301208, JP 8-146605, JP 8-211605, JP 8-129258 and JP 8-129259, herein incorporated in their entireties, describe how coumarin pigments can be used in combination with titanocene in lithographic printing.

JP A-2001-147526, herein incorporated in its entirety, discloses a photosensitive composition containing a combination of a titanocene compound and a halomethyl triazine compound having a phenyl group substituted with an alkoxy group.

JP-A-2001-100411, herein incorporated in its entirety, discloses a photosensitive composition containing a titanocene compound and a halomethyl triazine compound having a phenyl group substituted with a hydroxyl group or a carboxyl group.

JP-A-2001-66773, herein incorporated in its entirety, discloses a photosensitive composition containing a titanocene compound and a halomethyl oxadiazole compound.

JP 2003-162072, herein incorporated in its entirety, discloses a photosensitive composition containing a titanocene compound developed by alkali reagents, acetylene alcohol, an acetylene glycol and a polyoxyalkylene ether tenside.

EP 1510865 to Tatsuji, herein incorporated in its entirety, describes a photopolymerizable composition for lithographic printing plate having high sensitivity and good printing resistance using titanocene and triazine compounds.

U.S. Pat. No. 5,863,678 to Urano et al, herein, incorporated in its entirety, discloses compounds containing titanocenes and triazines with the addition of red, green or blue colorants. The addition of colourants enabling the resist material to be exposed to light generated from a high pressure mercury vapor lamp source producing high intensity light of the order of 70 or more mJ/cm².

WO 2006087102 to Baumann et al, herein incorporated in its entirety, provides a process for the production of lithographic printing plates using titanocene with an optimised developer.

EP 1,921,500 to Strehmel et al, herein incorporated in its entirety, discloses compounds containing titanocene and triarylamine compounds as stabilisers.

U.S. Pat. No. 7,316,887 to Urano, herein incorporated by reference in its entirety, describes the use of a dialkylaminobenzene compound as a sensitizing agent in conjunction with a titanocene compound enabling the use of blue laser light having a wavelength between 390 and 430 nm.

U.S. Pat. No. 8,114,569 to Holt, herein incorporated by reference in its entirety, describes the use of daylight active photoinitators incorporated into a photopolymer that is active enough to polymerise using an LCD screen as the illuminating source to make a flexographic printing plate. This patent discloses the use of organic carbonyl compounds, phosphine oxides, titanocene compounds and camphor quinone compounds as photoinitiators activated at a wavelength greater than 370 nm.

U.S. Pat. No. 8,632,9377 to Strehmel, herein incorporated by reference in its entirety, describes the use of certain benzoxazole derivatives as sensitisers in conjunction with titanocene compounds, to enhance the yellow light stability of the lithographic printing plate.

Exposing or encoding the image onto these lithographic printing plates can be carried out in an analogue manner by placing a negative or mask on the photosensitive side and irradiating it with light through the mask. To make a negative lithographic plate, the area on the film corresponding to the image on the plate is clear, while the non-image area is opaque. The coating beneath the clear film area is hardened by the incident light, while the area protected from the light remains un-crosslinked and can be removed during developing. The light-hardened surface of a negative working plate is therefore oleophilic and accepts printing ink, while the non-image area that used to be coated with the coating removed by the developer is desensitized and therefore hydrophilic.

Alternatively, these lithographic plates can also be exposed digitally without a film, e.g. with a UV or a blue light laser.

### DESCRIPTION OF THE INVENTION

It is an objective of this invention to provide an alternative method of making a lithographic printing plate using compounds that are activated in the daylight region without the drawbacks of previous methods. Previously known technologies have utilised daylight emitted from blue light lasers, surprisingly it has been found that very high resolution images can be obtained by exposing the polymer coating on a lithographic plate to visible light emitted directly from a liquid crystal display (LCD) screen.

Thus, in a first aspect of the invention is provided method of making a lithographic printing plate, the method comprising:
exposing a precursor plate to light to make a lithographic printing plate;
wherein the light is emitted from a liquid crystal display and wherein the precursor plate comprises:
   a substrate; and
   a light-sensitive photopolymer resin coated on the substrate, said resin comprising a titanocene photoinitiator.

This invention provides a novel method of digitally exposing the polymer on a lithographic plate. The image on the LCD comprises areas that emit light and those that do not. The portions of the photopolymer coating that correspond to the portions of the image that emit light are cured and those portions of the photopolymer coating that correspond to the portions of the image that do not emit light are not cured. Thus, the step of exposing the plate to light provides a lithographic printing plate precursor with a cured image.

Typically, the method further comprises, once the plate has been exposed to light, developing the plate by exposing it to a developer to remove uncured photopolymer resin to provide the lithographic printing plate. The plate may be suspended in the developer or the plate may be washed with the developer, e.g. by brushing or spraying the developer onto the plate.

LCD screens are available at considerably lower costs than lasers and they can now deliver high resolutions by virtue of high pixel densities. The polymer in this invention contains titanocene as the photoinitiator and it is activated by exposure to an image displayed on an LCD screen. Exposing a whole plate to an image created on an LCD screen is a faster method than using a laser in large formats as the entire area can be exposed simultaneously. It is therefore an effective and novel way of exposing lithographic printing plates providing surprisingly high resultant print resolutions, using low energy light generated from low cost exposure equipment.

Furthermore, the composition can be active enough to polymerise under the relatively low intensity of light emitted from a display screen intended for human viewing. The screen may be suitable for human viewing. The screen may be a screen of which less than 5% (e.g. less than 0.5%) of the light emitted by the screen is UV light, e.g. it may be that none of the light emitted is UV light. The screen may be an ‘off-the-shelf’ screen, e.g. a computer screen, monitor, laptop, tablet or mobile phone.

Furthermore, in the photopolymerisation of lithographic printing plates using titanocene initiators exposed by lasers, a scattering problem arises when the high intensity light reflects off the shiny base and tends to overexpose the image. This is not present in this invention where the illuminating light is an order of magnitude lower and its energy is absorbed and consumed at the thickness of the depth of cure.

This invention is a novel method for processing lithographic printing plates using the light emitted from a liquid crystal display (LCD) screen which is creating the image. The light emitted from LCD screens is typically daylight produced from an array of light emitting diodes (LED) backlighting the screen. LEDs produce a single frequency and therefore there is no UV produced from an unmodified screen. Thus the LCD may be backlit by LEDs.

It is an object of the present invention to provide a precursor plate suitable for making a lithographic printing plate. The precursor plate may comprise a substrate. The precursor plate may further comprise a light-sensitive photopolymer resin. The light-sensitive photopolymer resin may comprise a titanocene. The titanocene may be selected from bis(η⁵-2,4-cyclopentadien-1-yl)bis[2,6-difluoro-3-(1H-pyrrol-1-yl)phenyl]titanium, titanocene bis(trifluoromethanesulfonate), titanocene dichloride, (indenyl)titanium (IV) trichloride, (pentamethylcyclopentadienyl)titanium (IV) trichloride, cyclopentadienyltitanium (IV) trichloride, bis(cyclopentadienyl)titanium (IV) pentasulfide, (4R, 5R)-chloro-cyclopentadienyl-[2,2-dimethyl-1,3-dioxolan-4,5-bis(diphenylmethoxy)]titanium, (4S,5S)-chloro-cyclopentadienyl-[2,2-dimethyl-1,3-dioxolan-4,5-bis(diphenylmethoxy)]titanium or a mixture thereof. It may be that the total amount of titanocene present is from 0.5 to 5% by weight of the light-sensitive photopolymer resin. It may be that the total amount of titanocene present is from 0.9 to 2.5% by weight of the light-sensitive photopolymer resin.

In an embodiment of the present invention, the substrate is metal. In a preferred embodiment, the substrate is aluminium. In another preferred embodiment, the substrate is aluminium alloy.

In an embodiment, the thickness of the substrate is in the range from about 0.01 mm to about 10 mm. In a preferred embodiment, the thickness of the substrate is in the range from about 0.2 mm to 0.5 mm.

The thickness of the photopolymer coating is in the range from about 5 μm to about 250 μm. The thickness of the photopolymer coating may range from about 10 μm to about 30 μm.

It is an object of the present invention to provide a method of making a lithographic printing plate. The method may comprise exposing a light-sensitive photopolymer resin on a precursor plate to light to make a lithographic printing plate. The method may further comprise the light being emitted from a liquid crystal display.

An LCD typically consists of an array of pixels. Each pixel consists of a layer of molecules aligned between two transparent electrodes and two polarizing filters (parallel and perpendicular), the axes of transmission of which are, in most of the cases, perpendicular to each other. Before an electric field is applied, the orientation of the liquid-crystal molecules is determined by the alignment at the surfaces of electrodes. In the most commonly used twisted nematic device, the surface alignment directions at the two electrodes are perpendicular to each other and so the molecules arrange themselves in a helical structure. This induces the rotation of the polarization of the incident light, and the device appears grey. If the applied voltage is large enough, the liquid crystal molecules in the centre of the layer are almost completely untwisted and the polarization of the incident light is not rotated as it passes through the liquid crystal layer. This light will then be mainly polarized perpendicular to the second filter, and thus be blocked and the pixel will appear black. By controlling the voltage applied across the liquid crystal layer in each pixel, light can be allowed to pass through in varying amounts thus constituting different levels of grey.

Therefore, LCD screens provide both a low cost and a high resolution image creation source, but the light emitted (unless the backlight is modified) is entirely between 420 nm and 670 nm and is of relatively low intensity. The novel aspect of this invention is to enable this daylight part of the light spectrum, in relatively low intensity, to polymerise the lithographic coating.

The image is displayed digitally on the screen for a period of time just long enough to encode the image, with the photosensitive surface of the lithographic printing plate in contact with the screen, or separated by a clear film, for the duration of the exposure.

The light-sensitive photopolymer resin will typically comprise at least one monomeric or oligomeric chemical species comprising at least one carbon-carbon double bond that is polymerisable by free radical polymerisation, said monomeric or oligomeric chemical species being present in a total amount of from 25 to 99 wt %.

In the present invention, the at least one monomeric or oligomeric chemical species is a compound having a radically-polymerisable carbon-carbon double bond which undergoes addition polymerisation by the action of a photo-polymerisation initiation system when the photosensitive composition is selectively irradiated with daylight. Upon irradiation the polymer undergoes crosslinking and becomes tough and resilient. In the areas where it is not irradiated it can be removed by suspension in a developer. The at least one monomeric or oligomeric chemical species is chosen to provide the desired rate of polymerisation, toughness and crosslinking properties while delivering the resulting increase in difference in solubility of the exposed portions and non-exposed portions of the photosensitive composition after exposure to the developer.

It may be that the at least one monomeric or oligomeric chemical species has one carbon-carbon double bond in a molecule, and specifically, it may, for example, be an unsaturated carboxylic acid such as acrylic acid, methacrylic acid, crotonic acid, isocrotonic acid, maleic acid, itaconic acid or citraconic acid, an alkyl ester thereof, (meth)acrylonitrile, (meth)acrylamide or styrene. However, preferably the compound has at least two carbon-carbon double bonds.

Suitable monomeric or oligomeric chemical species include an ester of an unsaturated carboxylic acid with an aliphatic polyhydroxyl compound, a phosphate containing an acryloyloxy group or a methacryloyloxy group, a urethane (meth)acrylate or an epoxy (meth)acrylate.

The ester of unsaturated carboxylic acid with an aliphatic polyhydroxyl compound may be an ester of the above-mentioned unsaturated carboxylic acid with an aliphatic polyhydroxyl compound such as ethylene glycol, diethylene glycol, triethylene glycol, tetraethylene glycol, propylene glycol, trimethylene glycol, 1,3-butanediol, tetramethylene glycol, neopentyl glycol, hexamethylene glycol, trimethylolethane, trimethylolpropane, glycerol, pentaerythritol, dipentaerythritol or sorbitol. Specific examples of the ester include ethylene glycol di(meth)acrylate, diethylene glycol di(meth)acrylate, triethylene glycol di(meth)acrylate, tetraethylene glycol di(meth)acrylate, propylene glycol di(meth)acrylate, 1,3-butanedioldi(meth)acrylate, tetramethylene glycol di(meth)acrylate, neopentyl glycol di(meth)acrylate, hexamethylene glycol di (meth)acrylate, trimethylolethane tri(meth)acrylate, tetramethylolethane tri(meth)acrylate, trimethylolpropane tri(meth)acrylate, glycerol di(meth)acrylate, glycerol tri(meth)acrylate, pentaerythritol di(meth)acrylate, pentaerythritol tri(meth)acrylate, pentaerythritol tetra(meth)acrylate, dipentaerythritol di(meth)acrylate, dipentaerythritol tetra(meth)acrylate, dipentaerythritol penta(meth)acrylate, dipentaerythritol hexa(meth)acrylate, sorbitol tri(meth)acrylate, sorbitol tetra(meth)acrylate, sorbitol penta(meth)acrylate and sorbitol hexa(meth)acrylate, and similar crotonates, isocrotonates, maleates, itaconates and citraconates. The phosphate containing an acryloyloxy group or a methacryloyloxy group must have a (meth)acryloyloxy group in its structure.

The urethane (meth)acrylate may, for example, be a urethane (meth)acrylate of a polyisocyanate compound such as an aliphatic polyisocyanate such as hexamethylene diisocyanate or trimethylhexamethylene diisocyanate, an alicyclic polyisocyanate such as cyclohexane diisocyanate or isophorone diisocyanate or an aromatic polyisocyanate such as tolylene diisocyanate, xylylene diisocyanate or diphenylmethane diisocyanate, with an unsaturated hydroxyl compound such as hydroxymethyl (meth)acrylate, hydroxyethyl (meth)acrylate, glycerol di(meth)acrylate, pentaerythritol tri(meth)acrylate or tetramethylolethane tri(meth)acrylate. Specifically, hexamethylene bis[(meth)acryloyloxy methylurethane], hexamethylene bis[(meth)acryloyloxy ethylurethane], hexamethylene bis {tris[(meth)acryloyloxymethyl] methylurethane} or hexamethylene bis {tris[(meth)acryloyloxymethyl] ethylurethane)}.

The epoxy (meth)acrylate may, for example, be an epoxy (meth)acrylate of a polyepoxy compound such as (poly)ethylene glycol polyglycidyl ether, (poly)propylene glycol polyglycidyl ether, (poly)tetramethylene glycol polyglycidyl ether, (poly)pentamethylene glycol polyglycidyl ether, (poly)neopentyl glycol polyglycidyl ether, (poly)hexamethylene glycol polyglycidyl ether, (poly)trimethylolpropane polyglycidyl ether, (poly)glycerol polyglycidyl ether or (poly)sorbitol polyglycidyl ether, with a hydroxy (meth)acrylate compound such as hydroxymethyl (meth)acrylate or hydroxyethyl (meth)acrylate.

Preferred monomeric or oligomeric chemical species are (meth)acryloyloxy group- containing phosphates and urethane (meth)acrylates.

Preferably the at least one monomeric or oligomeric chemical species comprises a urethane compound and it contains at least four urethane linkages and at least four addition-polymerisable double bonds in each molecule. The urethane compound can be constructed by reacting an isocyanate with a polyol having at least one hydroxyl group and at least two addition-polymerisable double bonds in one molecule. The number of the isocyanate groups can be adjusted to match the number of hydroxyl groups in the polyol. The molecular weight of compound is usually between 10,000 and at most 150,000. If the molecular weight is beyond this range, sensitivity of the photosensitive composition tends to decrease.

This compound will have at least one hydroxyl group and at least two addition-polymerisable double bonds in one molecule It may for example, be a compound having at least one alcoholic hydroxyl group, prepared by esterification of a compound having a plurality of alcoholic hydroxyl groups such as a polyhydric alcohol with a compound containing a carboxyl group and a (meth)acryloyl group.

More specifically, it may be a hydroxyl group-containing multi-functional acrylate compound having at least one alcoholic hydroxyl group, which is an ester of a polyhydric alcohol with acrylic acid, such as a compound prepared by reaction of 3 moles of acrylic acid with 1 mole of pentaerythritol, a compound prepared by reaction of 2 moles of acrylic acid with 1 mole of pentaerythritol, a compound prepared by reaction of 5 moles of acrylic acid with 1 mole of dipentaerythritol, or a compound prepared by reaction of 4 moles of acrylic acid with 1 mole of dipentaerythritol, and specific examples include pentaerythritol triacrylate, pentaerythritol diacrylate, dipentaerythritol diacrylate, dipentaerythritol triacrylate, dipentaerythritol tetraacrylate and dipentaerythritol pentaacrylate. Such a compound may be used on its own or as part of a photosensitive composition.

The reaction of the isocyanate with the hydroxyl group can be carried out in a stainless steel or glass vessel according to proportions determined by their OH values addition in the presence of a catalyst such as n-butyl tin dilaurate by anyone experienced in the art. The resultant urethane compound may be used alone or used in combination with other reactive diluents. A functional group other than the addition-polymerisable double bond may be introduced into the molecule for the purpose of controlling various properties of the photosensitive composition.

The photopolymerisation initiation system may contain a radical generator and may further contain a hydrogen-donor compound as a polymerisation accelerator as the case requires. The radical generator is a compound which receives light excitation energy and generates active radicals by the absorbed energy, and causes the at least one monomeric or oligomeric chemical species to undergo polymerisation.

The radical generator in the present invention may be a titanocene compound combined with any other photoinitiator activated in the daylight region, such as Irgacure 819, Eosin Y, Camphor Quinone or Spectra Groups range of H-Nu 470, H-Nu 535, H-Nu 635, amongst others.

Suitable titanocene compounds include titanium compounds having a dicyclopentadienyl structure and a biphenyl structure, such as dicyclopentadienyl titanium dichloride, dicyclopentadienyl titanium bisphenyl, dicyclopentadienyl titanium bis(2,4-difluorophenyl), dicyclopentadienyl titanium bis(2,6-difluorophenyl), dicyclopentadienyl titanium bis(2,4,6-trifluorophenyl), dicyclopentadienyl titanium bis(2,3,5,6-tetrafluorophenyl), dicyclopentadienyl titanium bis(2,3,4,5,6-pentafluorophenyl), di(methylcyclopentadienyl) titanium bis(2,6-difluorophenyl), di(methylcyclopentadienyl) titanium bis(2,3,4,5,6-pentafluorophenyl) or dicyclopentadienyl titanium bis[2,6-difluoro-3-(1-pyrrolyl)phenyl]. Preferably the titanocene compound is bis(η⁵-2,4-cyclopentadien-1-yl)-bis(2,6-difluoro-3-(1H-pyrrol-1-yl)-phenyl) titanium.

It may be that the composition also includes a coinitiator. This serves to speed up the reaction. The coinitiator can be present from 0.5 to 10% by weight of the light-sensitive photopolymer resin. It may be that the total amount of coinitiator present is from 1 to 5% by weight of the light-sensitive photopolymer resin. It may be that the total amount of coinitiator present is from 1.5 to 5% by weight of the light-sensitive photopolymer resin. It may be that the total amount of coinitiator present is from 1.5 to 5% by weight of the light-sensitive photopolymer resin and the total amount of titanocene present is from 0.9 to 2.5% by weight of the light-sensitive photopolymer resin. It may be that the total amount of coinitiator present is from 2 to 4% by weight of the light-sensitive photopolymer resin.

It has been found that the rate of polymerisation can be greatly enhanced by the addition of at least one coinitiator. A coinitiator as referred to in the present invention is a compound that can generate free radicals when itself activated by the activated photoinitiator but which does not itself absorb light in the visible spectrum. The coinitiators can for example be selected from onium compounds, for example those where the onium cation is selected from iodonium, sulfonium, phosphonium, oxylsulfoxonium, oxysulfonium, sulfoxonium, ammonium, diazonium, selenonium, arsenonium and N-substituted N-heterocyclic onium cations wherein N is substituted with an optionally substituted alkyl, alkenyl, alkinyl or aryl (e.g. N-alkoxypyridinium salts); N-arylglycines and derivatives thereof (e.g. N-phenylglycine); aromatic sulfonyl halides; trihalomethylsulfones; imides such as N-benzoyloxyphthalimide; diazosulfonates; 9,10-dihydroanthracene derivatives; N-aryl, S-aryl or O-aryl polycarboxylic acids with at least two carboxy groups of which at least one is bonded to the nitrogen, oxygen or sulfur atom of the aryl unit (e.g. aniline diacetic acid and derivatives thereof, hexaarylbiimidazoles; thiol compounds (otherwise known as mercaptans) (e.g. mercaptobenzthiazoles, mercaptooxadiazoles, mercaptotetrazines, mercaptoimidazoles, mercaptotetrazoles, mercaptopyridines, mercaptooxazoles and mercaptotriazoles; they include 2-mercaptobenzoxazole, 2-mercaptobenzothiazole, 2-mercaptobenzimidazole, pentaerythritol-tetrakis(mercaptoacetate), 4-acetamidothiophenol, mercaptosuccinic acid, dodecanthiol, betamercaptoethanol, 6-ethoxy-2-mercaptobenzothiazole, 4-methyl-4H-1,2,4-triazole-3-thiol, 2-mercapto-1-methylimidazole, 2-mercapto-5-methylthio-1,3,4-thiadiazole, 5-n-butylthio-2-mercapto-1,3,4-thiadiazole, 4-methoxybenzene thiol, 1-phenyl-1H-tetrazole-5-thiol, 4-phenyl-4H-1,2,4-triazole-3-thiol, pentaerythritol-tetrakis(3-mercaptopropionate), trimethylolpropane-tris(mercaptoacetate), 2-mercaptopyridine, 4-mercaptopyridine, 2-mercapto-3H-quinazoline and 2-mercaptothiazoline); 1,3,5-triazine derivatives with 1 to 3 CX₃ groups (wherein every X is independently selected from a chlorine or bromine atom, and is preferably a chlorine atom), such as e.g. 2-phenyl-4,6-bis(trichloromethyl)-s-triazine, 2,4, 6-tris(trichloromethyl)-s-triazine, 2-methyl-4,6-bis(trichloromethyl)-s-triazine, 2-(styryl-4,6-bis(trichloromethyl)-s-triazine, 2-(p-methoxystyryl)-4,6-bis(trichloromethyl)-s-triazine, 2-(4-methoxy-naphtho-1-yl)-4,6-bistrichloromethyl-s-triazine, 2-(4-ethoxy-naphtho-1-yl)-4,6-bis(trichloromethyl)-s-triazine and 2-[4-(2-ethoxyethyl)-naphtho-1-yl]-4,6-bis(trichloromethyl)-s-triazine; oxime ethers and oxime esters, such as for example those derived from benzoin; α-hydroxy or α-amino acetophenones; mono-, di- and triacylphosphine oxides, and peroxides.

Preferably, the coinitiator comprises thiol groups. Thus, the coinitiator may be a compound defined by the formula X-(SH)n where X represents any organic moiety, and n represents a number from 1 to 10. Thus, the coinitiator may be selected from 2-mercaptobenzoxazole, 2-mercaptobenzothiazole, 2-mercaptobenzimidazole, pentaerythritol-tetrakis(mercaptoacetate), 4-acetamidothiophenol, mercaptosuccinic acid, dodecanthiol, betamercaptoethanol, 6-ethoxy-2-mercaptobenzothiazole, 4-methyl-4H-1,2,4-triazole-3-thiol, 2-mercapto-1-methylimidazole, 2-mercapto-5-methylthio-1,3,4-thiadiazole, 5-n-butylthio-2-mercapto-1,3,4-thiadiazole, 4-methoxybenzene thiol, 1-phenyl-1H-tetrazole-5-thiol, 4-phenyl-4H-1,2,4-triazole-3-thiol, pentaerythritol-tetrakis(3-mercaptopropionate), trimethylolpropane-tris(mercaptoacetate), 2-mercaptopyridine, 4-mercaptopyridine, 2-mercapto-3H-quinazoline and 2-mercaptothiazoline or a mixture thereof. The coinitiator may be an oligomeric moiety comprising thiol groups, e.g. a mercaptomodified polyester acrylate.

A thiol group is a —S—H group, the —S—H group being typically attached to a carbon atom in an organic moiety. Such groups are sometimes referred to as mercaptans. A thiol coinitiator is a coinitiator that comprises a thiol group.

An ‘organic moiety’ is intended to mean any hydrocarbyl group or group of hydrocarbyl groups, for example one or more hydrocarbyl group selected from an alkyl group, cycloalkyl group, aromatic group, heteroaromatic group, heterocyclic group, alkenyl group, any of said groups being substituted by or linked together by an aldehyde, halogen, ketone, carboxyllic acid or ester, ether, thioether, amine, amide functionality.

It has been found that thiol or mercaptan coinitiators are particularly suitable to enhance the rate of growth of polymer when irradiated with low intensity daylight and also provide the finished object with a dry surface finish.

The light-sensitive photopolymer resin preferably contains a polymer binder. This has the purpose of improving properties of the plate, e.g. development properties, or to improve coating properties when the photosensitive layer is coated on a substrate.

Specific examples of the polymer binder include homopolymers and copolymers of, e.g. (meth)acrylic acid, (meth)acrylic ester, (meth)acrylamide, maleic acid, (meth)acrylonitrile, styrene, vinyl acetate, vinylidene chloride and maleimide, and polyethylene oxide, polyvinyl pyrrolidone, polyamide, polyurethane, polyester, polyether, polyethylene terephthalate, acetyl cellulose and polyvinyl butyral. Of these binder materials, preferred is a copolymer containing carboxyl groups.

The light-sensitive photopolymer resin may comprise at least one stabiliser that prevents degradation of the cured polymer during plate life. Exemplary stabilisers include hindered amine light stabilisers (HALS) which deactivate the free radicals such as tetramethyl piperidine derivatives. Further exemplary stabilisers include sterically hindered monophenols, e.g. 2,6-di-tert-butyl-p-cresol or Butylated Hydroxy Toluene (BHT). Further exemplary stabilisers include alkylated thiobisphenols, e.g. 2,2-methylenebis-(4-methyl-6-tert-butylphenol) and 2,2-bis(1-hydroxy-4-methyl-6-tert-bytylphenyl) sulfide. The photopolymer formulation may comprise two stabilisers, the stabilisers being 2,6-di-tertiarybutyl-4-methyl phenol and a disubstituted diphenyl amine. Alternatively, the photopolymer formulation may be free of stabilisers. The photopolymer formulation may comprise no stabilisers other than those which prevent degradation of the cured polymer and/or those which prevent over-cure.

It has been found that these daylight activated formulations do not require any additional stabilisers to prevent over-cure as the intensity of light present in non-intended areas is below the threshold necessary to initiate polymerisation. This is a surprising discovery with ramifications in the creation of accurate high resolution lithographic printing plates.

The substrate may be any of the conventional ones used for photosensitive lithographic printing plates. It may, for example, be a metal plate of aluminum, zinc, iron, copper or an alloy thereof, a metal plate having chromium, zinc, copper, nickel, aluminum, iron or the like, plated or vapor-deposited thereon, a paper sheet, a plastic film, a glass sheet, a resin- coated paper sheet, a paper sheet having a metal foil such as an aluminum foil bonded thereto, or a plastic film having hydrophilic treatment applied thereto. Preferred is a plate of aluminum or an aluminum alloy. The thickness of the aluminum lithographic precursor plate usually ranges from about 0.01 to about 10 mm, preferably from about 0.2 to 0.5 mm.

The aluminum plate which has been surface roughened is further subjected to a desmutting treatment with an aqueous acid or alkali solution as the case requires. The desmutting treatment is conducted by soaking the plate in an aqueous solution of an acid such as sulfuric acid, nitric acid, hydrochloric acid, phosphoric acid or chromic acid, or in an aqueous solution of an alkali such as sodium hydroxide, potassium hydroxide, sodium metasilicate, sodium phosphate, sodium pyrophosphate, potassium phosphate or sodium aluminate, or by spraying one of these aqueous solutions onto the plate. The aluminum plate is then usually subjected to an anodic oxidation treatment, particularly preferably a treatment with an electrolytic solution containing sulphuric acid typically at 25% concentration and delivered at about 35° C. for about a minute.

The residual amount of the smut is preferably in the range from 0.32 to 0.45, as shown by the reflection density on the surface on the photosensitive composition side. When the reflection ratio is within this range the printing resistance will improve.

The photosensitive composition may then be coated on a surface by dip coating, spray coating or by coating bar or similar. The thickness of coating varies upon use, but is typically between 2 and 4 g/m². The drying temperature is typically between 80° C. and 100° C. and the drying time is about 15 minutes.

A protective layer may be laid on top of the photosensitive layer in order to prevent inhibition due to the presence of oxygen. Specific examples of protective layers are those formed from water-soluble polymers such as a polyvinyl alcohol, polyvinyl pyrrolidone, polyethylene oxide and cellulose. Preferably this layer is a polyvinyl alcohol and polyvinyl pyrrolidone in combination.

The photosensitive lithographic printing plate of the present invention may be formed in a manner such that the photosensitive layer consists of a photosensitive composition has a peak of spectral sensitivity between 400 and 700 nm. A preferred aspect of the invention is that the photosensitive composition which constitutes the photosensitive layer in the above case, is one in which the polymerization initiation system contains a titanocene compound.

The source of light for image formation is not particularly limited as long as it is daylight emitted from a display screen between 400 to 700 nm. Although it is possible to utilise light from the blue, green and red pixels, in practice the majority of the usable light is emitted from the blue pixel.

Exposure of the lithographic printing plate is conducted by placing the coated side of the plate in direct contact with the display screen and leaving it in contact for the time necessary to expose it, this depends upon the luminance of the screen and the reactivity of the composition, but typically between 1 second and 180 seconds, preferably between 15 seconds and 60 seconds.

It may be desirable to protect the screen from being in direct contact with the polymer and in which case it can separated by a film of plastic, such as polypropylene, polyester, polytetrafluoroethylene, perfluoroalkoxy copolymer or more desirably a fluorinated ethylene propylene film. The film may have a thickness from μm to 250 μm, but preferably it is 25 μm thick.

The photosensitive lithographic printing plate of the present invention is image-wise exposed by means of the above light source, followed by development of the image with an aqueous developer consisting mainly of water, preferably with an aqueous solution containing a surface active agent and an alkali component.

The aqueous solution may further contain an organic solvent; and/or an inorganic alkali compound such as sodium silicate, potassium silicate, sodium hydroxide, potassium hydroxide, lithium hydroxide, tribasic sodium phosphate, dibasic sodium phosphate, sodium carbonate, potassium carbonate and sodium bicarbonate; and/or an organic amine compound such as trimethylamine, diethylamine, isopropyl amine, n-butylamine, monoethanolamine, diethanolamine and triethanolamine. These compounds may be used alone or in combination. The pH of the alkali developer usually ranges from about 9 to about 14, preferably from 11 to 13.

Surface active agents include a nonionic surface active agent such as a polyoxyethylene alkyl ether, a polyoxyethylene alkyl aryl ether, a polyoxyethylene alkyl ester, a sorbitan alkyl ester or a monoglyceride alkyl ester, an anionic surface active agent such as an alkyl benzene sulfonate, an alkyl naphthalene sulfonate, an alkyl sulfate, an alkyl sulfonate or a sulfosuccinate, or an ampholytic surface active agent such as an alkyl betaine or an amino acid.

Suitable organic solvents include isopropyl alcohol, benzyl alcohol, ethyl cellosolve, butyl cellosolve, phenyl cellosolve, propylene glycol and diacetone alcohol.

It has been found that developers that comprise alkoxylated derivatives as well tetramethyl ammonium hydroxide lead to strong dot sharpening in lithographic printing plates. The improved sensitivity of these visible light activated lithographic plates has led to the creation of new developers providing faster processing speed while still transferring consistent tonal values. It is possible that the development process is completed separately or when the plate is coated with ink and is in use.

The method of development employed is not particularly limited, and may be conducted by soaking the plate in the developer or by physically removing non-image portions by brushing or spraying the developer onto the plate. The time for development is long enough to remove all the non-image portions and is typically about 3 to 5 minutes. After developing, the plate may be subjected to a hydrophilic treatment by applying gum arabic.

The following examples of this invention are not intended to be limiting unless otherwise specified.

### Example 1

An aluminum plate with dimensions of 225 mm×145 mm with a thickness of 0.3 mm was degreased with a 3 wt. % aqueous sodium hydroxide solution, subjected to electrolytic etching in a hydrochloric acid bath of 11.5 g/1 at 25° C. at a current density of 80 A/dm² for 11 seconds, and washed with water. Then, the plate was subjected to anodic oxidation in a sulfuric acid bath of 30 wt. % at 30° C. at 11.5 A/dm² for 15 seconds, washed with water and dried.

A protective layer coating was constructed by mixing 90 g of polyvinyl alcohol, 5 g of polyvinyl pyrrolidone and 1000 g of distilled water. This coating was applied with a bar coater and dried at 170° C. for 2 minutes so that the dried film thickness was 3 g/m2.

100 g of a photosensitive coating was constructed by mixing 22 g of a binder, cellulose acetate butyrate (CAS Number 9004-36-8 from Sigma Aldrich), 32.9 g of a hexafunctional aliphatic urethane acrylate oligomer Ebecryl 1290 from Allnex, 22 g of a tetrafunctional reactive diluent in PETIA from Allnex which is a mixture of pentaerythritol tri and teraacrylates, 2.1 g of Irgacure 784 from BASF, 18 g of an organic solvent dimethylformamide and 3 g of Capstone Fluorosurfactant 1157D from Dupont a surfactant to reduce surface tension.

The photosensitive composition was mixed at room temperature in a glass vessel for 2 hours. It was then applied by a knife coater on the pre-treated aluminum substrate. The thickness of the undried layer was set to 15 my. The coated sheet was then dried in an oven at 70° C. for 10 minutes.

The coated sheet was placed coated surface down onto a 10.1″ high brightness LCD display screen. The screen was selected to provide a combination of high brightness for speed of cure, high pixel density for plate resolution and high contrast to prevent overcure. By experimentation a screen with these properties was found to be model number 13-101ZMLB00A0-S made by DigiWise International Corporation of Taiwan. The 225×145 mm aluminium sheet was placed on top of the screen which had an active area of 217 mm×135 mm. The screen had a 1280×800 pixel resolution, a 450 candela/m² luminance and 700:1 contrast ratio. The desired image to be encoded onto to the lithographic printing plate was sent as a black and white file from a computer via the driver board to the LCD array and was left illuminated for the necessary exposure time. The luminance of the screen and the reactivity of the photosensitive layer defined the exposure time and by experimentation this was found to be optimised at 65 seconds.

The development of the aluminium plate was carried by placing it in a bath of developing liquid, made from mixing 250 g of toluene and 250 g of 4-butyrolactone. It was left in the bath for 22 sec at a temperature of 23° C. After the development, the plate was be subjected to a hydrophilic treatment by applying gum arabic.

The image produced was an excellent representation of the digital image on the lithographic plate surface.

### Example 2

### Alternative Coating Formulation

An aluminum plate was made in the same manner as shown in Example 1. It was coated with a protective layer in the same manner as shown in Example 1.

An alternative photosensitive formulation was constructed in the following manner.

100 g of a photosensitive coating was constructed by mixing 15 g of N-methyl-2-pyrrolidone (CAS number 872-50-4 from Sigma Aldrich), 32.9 g of a urethane acrylate oligomer Ebecryl 452 from Allnex, 22 g of a reactive diluent Ebecryl 140 from Allnex, 2.1 g of Irgacure 784 from BASF, 10 g of a solvent methyl ethyl ketone, 15 g of a solvent propylene glycol monomethyl ether and 3 g of Modaflow 9200 from Allnex, a flow modifier.

The sheet was coated, dried, exposed, developed and post treated in the same manner as shown in Example 1. The image produced was an excellent representation of the digital image on the lithographic plate surface.

### Example 3

### Alternative Coating Formulation

An aluminum plate was made in the same manner as shown in Example 1. It was coated with a protective layer in the same manner as shown in Example 1.

An alternative photosensitive formulation was constructed in the following manner.

100 g of a photosensitive coating was constructed by mixing 11 g of a binder, polyvinyl pyrrolidone (CAS number 108-94-1 from Sigma Aldrich), 32.7 g of a trifunctional aliphatic urethane acrylate oligomer Ebecryl 294/25HD, 30 g of a tetrafunctional reactive diluent Dipentaerythritol Hexaacrylate from Allnex, 2.1 g of Irgacure 784 from BASF, 24 g of a solvent Cyclohexanone and 0.2 g of Tinuvin 292 from BASF.

The sheet was coated, dried, exposed, developed and post treated in the same manner as shown in Example 1. The image produced was an excellent representation of the digital image on the lithographic plate surface.

Example 4

### Alternative Screen

An aluminum plate was made in the same manner as shown in Example 1. It was coated with a protective layer in the same manner as shown in Example 1. 100 g of a photosensitive coating was constructed as shown in Example 3. This was coated and dried in the same manner as in previous examples.

The coated sheet was placed coated surface down onto a 10.1″ high brightness LCD display screen. The screen was selected to provide a combination of high brightness for speed of cure, high pixel density for plate resolution and high contrast to prevent overcure. The screen used was model number DLH1015-INN-G01 made by Litemax. The 225×145 mm aluminium sheet was placed on top of the screen which had an active area of 217 mm×135 mm. The screen had a 1280×800 pixel resolution, a 1000 candela/m² luminance and 800:1 contrast ratio. The desired image to be encoded onto to the lithographic printing plate was sent as a black and white file from a computer via the driver board to the LCD array and was left illuminated for the necessary exposure time. The luminance of the screen and the reactivity of the resin defines the exposure time and by experimentation this was found to be optimised at 45 seconds.

The development and post development treatment of the plate was carried out as described in example 3. The image produced was an excellent representation of the digital image on the lithographic plate surface.

### Example 5

### Alternative Coating Formulation Using a Coinitiator

An aluminum plate was made in the same manner as shown in Example 1. It was coated with a protective layer in the same manner as shown in Example 1.

An alternative photosensitive formulation was constructed in the following manner.

100 g of a photosensitive coating was constructed by mixing 11 g of a binder, polyvinyl pyrrolidone (CAS number 108-94-1 from Sigma Aldrich), 31.6 g of a trifunctional aliphatic urethane acrylate oligomer Ebecryl 294/25 HD, 28.1 g of a tetrafunctional reactive diluent Dipentaerythritol Hexaacrylate from Allnex, 2.1 g of Irgacure 784 from BASF, 24 g of a solvent Cyclohexanone, 0.2 g of Tinuvin 292 from BASF and 3 g of PETMP pentaerythritol tetra(3-mercaptopropionate) from Bruno Bock.

The sheet was coated, dried in the same manner as Example 1. Instead of 65 seconds the formulation was found to cross-link satisfactorily at only 38 seconds exposure. The sheet was developed and post treated in the same manner as shown in Example 1. The image produced was an excellent representation of the digital image on the lithographic plate surface.

1. A method of making a lithographic printing plate, the method comprising:
exposing a precursor plate to visible light to make a lithographic printing plate;
wherein the light is emitted from a liquid crystal display and wherein the precursor plate comprises:
a substrate; and
a light-sensitive photopolymer resin coated on the substrate, said resin comprising a titanocene photoinitiator.

2. The method of claim 1, wherein the photoinitiator is selected from the group consisting of bis(η⁵-2,4-cyclopentadien-1-yl)bis[2,6-difluoro-3-(1H-pyrrol-1-yl)phenyl]titanium, titanocene bis(trifluoromethanesulfonate), titanocene dichloride, (indenyl)titanium (IV) trichloride, (pentamethylcyclopentadienyl)titanium (IV) trichloride, cyclopentadienyltitanium (IV) trichloride, bis(cyclopentadienyl)titanium (IV) pentasulfide, (4R, 5R)-chloro-cyclopentadienyl-[2,2-dimethyl-1,3-dioxolan-4,5-bis(diphenylmethoxy)]titanium, (4S,5S)-chloro-cyclopentadienyl-[2,2-dimethyl-1,3-dioxolan-4,5-bis(diphenylmethoxy)]titanium and a mixture thereof.

3. The method of claim 1, wherein the substrate is metal.

4. (canceled)

5. The method of claim 1, wherein the thickness of the photopolymer coating is in the range from about 5 μm to about 250 μm.

6. The method of claim 1, wherein the photopolymer resin further comprises at least one coinitiator.

7. The method of claim 6, wherein the coinitiator is selected from the group consisting of 2-mercaptobenzoxazole, 2-mercaptobenzothiazole, 2-mercaptobenzimidazole, pentaerythritol-tetrakis(mercaptoacetate), 4-acetamidothiophenol, mercaptosuccinic acid, dodecanthiol, betamercaptoethanol, 6-ethoxy-2-mercaptobenzothiazole, 4-methyl-4H-1,2,4-triazole-3-thiol, 2-mercapto-1-methylimidazole, 2-mercapto-5-methylthio-1,3,4-thiadiazole, 5-n-butylthio-2-mercapto-1,3,4-thiadiazole, 4-methoxybenzene thiol, 1-phenyl-1H-tetrazole-5-thiol, 4-phenyl-4H-1,2,4-triazole-3-thiol, pentaerythritol-tetrakis(3-mercaptopropionate), trimethylolpropane-tris(mercaptoacetate), 2-mercaptopyridine, 4-mercaptopyridine, 2-mercapto-3H-quinazoline, 2-mercaptothiazoline and a mixture thereof.

8. (canceled)

9. The method of claim 6, wherein the total amount of coinitiator present is from 0.5 to 10 wt % by weight of the light-sensitive photopolymer resin.

10. The method of claim 1, wherein the total amount of photoinitiator present is from 0.5 to 5% by weight of the light-sensitive photopolymer resin.

11. The method of claim 1, wherein the light emitted from the liquid crystal display contains only visible light.

12. The method of claim 1, wherein the liquid crystal display is selected from the group consisting of a light emitting diode type (LED), an organic light emitting diode type (OLED), a polymer light emitting diode type (PLED) and a plasma display panel type (PDP).

13-15. (canceled)

16. The method of claim 1, wherein the display screen has a luminescence of between 100 and 2000 candela per square metre.

17. (canceled)

18. The method of claim 1, wherein the method further comprises, once the plate has been exposed to light, developing the plate by exposing it to a developer to remove uncured photopolymer resin.

19. A precursor plate suitable for making a lithographic printing plate when exposed to visible light, the precursor plate comprising:
a substrate; and
a light-sensitive photopolymer resin coated on the substrate, the light sensitive resin comprising a titanocene photoinitiator selected from the group consisting of bis(η⁵-2,4-cyclopentadien-1-yl)bis[2,6-difluoro-3-(1H-pyrrol-1-yl)phenyl]titanium, titanocene bis(trifluoromethanesulfonate), titanocene dichloride, (indenyl)titanium (IV) trichloride, (pentamethylcyclopentadienyl)titanium (IV) trichloride, cyclopentadienyltitanium (IV) trichloride, bis(cyclopentadienyl)titanium (IV) pentasulfide, (4R, 5R)-chloro-cyclopentadienyl-[2,2-dimethyl-1,3-dioxolan-4,5-bis(diphenylmethoxy)]titanium, (4S,5S)-chloro-cyclopentadienyl-[2,2-dimethyl-1,3-dioxolan-4,5-bis(diphenylmethoxy)]titanium and a mixture thereof.

20. The plate of claim 19, wherein the substrate is metal.

21. (canceled)

22. The plate of claim 19, wherein the thickness of the photopolymer coating is in the range from about 5 μm to about 250 μm.

23. The plate of claim 19, wherein the photopolymer further comprises at least one coinitiator.

24. The plate of claim 23, wherein the coinitiator is selected from the group consisting of 2-mercaptobenzoxazole, 2-mercaptobenzothiazole, 2-mercaptobenzimidazole, pentaerythritol-tetrakis(mercaptoacetate), 4-acetamidothiophenol, mercaptosuccinic acid, dodecanthiol, betamercaptoethanol, 6-ethoxy-2-mercaptobenzothiazole, 4-methyl-4H-1,2,4-triazole-3-thiol, 2-mercapto-1-methylimidazole, 2-mercapto-5-methylthio-1,3,4-thiadiazole, 5-n-butylthio-2-mercapto-1,3,4-thiadiazole, 4-methoxybenzene thiol, 1-phenyl-1H-tetrazole-5-thiol, 4-phenyl-4H-1,2,4-triazole-3-thiol, pentaerythritol-tetrakis(3-mercaptopropionate), trimethylolpropane-tris(mercaptoacetate), 2-mercaptopyridine, 4-mercaptopyridine, 2-mercapto-3H-quinazoline, 2-mercaptothiazoline and a mixture thereof.

25. (canceled)

26. The plate of claim 23, wherein the total amount of coinitiator present is from 0.5 to 10 wt % by weight of the light-sensitive photopolymer resin.

27. The plate of claim 19, wherein the total amount of photoinitiator present is from 0.5 to 5% by weight of the light-sensitive photopolymer resin.

28. The plate of claim 19, wherein the photoinitiator is bis(η⁵-2,4-cyclopentadien-1-yl)bis(2,6-difluoro-3-(1H-pyrrol-1-yl)-phenyl) titanium.
